(19) United States
(12) Patent Application Publication
(10) Pub. No.: US 2024/0304120 A1
(43) Pub. Date: Sep. 12, 2024

(54) TILED DISPLAY AND MANUFACTURING METHOD THEREOF

(71) Applicant: CCS Technology Corporation, Taoyuan City (TW)

(72) Inventors: Cheng-Hung Chung, Taoyuan City (TW); Chang-Cheng Lo, Taoyuan City (TW); Tung-Po Sung, Taoyuan City (TW)

(73) Assignee: CCS Technology Corporation, Taoyuan City (TW)

(21) Appl. No.: 18/306,885

(22) Filed: Apr. 25, 2023

(30) Foreign Application Priority Data
Mar. 6, 2023 (TW) 112108020

(51) Int. Cl. G09F 9/302; G09F 9/30; H01L 25/16; H01L 27/12; H01L 33/62

(52) U.S. Cl. CPC G09F 9/3026; G09F 9/301; H01L 25/167; H01L 27/124; H01L 33/62; H01L 2933/0066

(57) ABSTRACT

The present invention discloses a tiled display comprising a plurality of display panels tiled with each other, and each of the display panels comprises: a transparent rigid motherboard with a top surface and a bottom surface opposite to each other; and a flexible display panel formed on the transparent rigid motherboard, wherein the flexible display panel comprises a flexible substrate, a pixel area, a first external circuit area and a second external circuit area. The pixel area, the first external circuit area and the second external circuit area are formed on the flexible substrate, and the pixel area is located on the top surface of the transparent rigid motherboard, and the first external circuit area and the second external circuit area are located outside of the pixel area and respectively electrically connected to a plurality of first scanning lines and a plurality of first data lines of the pixel area, and the first external line area and the second external circuit area are respectively back-folded and fastened on the bottom surface of the transparent rigid motherboard.

This application claims the benefit of Taiwanese application serial No. 112108020, filed on Mar. 6, 2023, and the subject matter of which is incorporated herein by reference.

### BACKGROUND OF THE INVENTION

### Field of the Invention

The invention relates in general to a display and manufacturing method thereof, and in particular relates to a tiled display and manufacturing method thereof.

### Description of the Related Art

Large-size displays have been widely used in the field of public information display (for example: large outdoor billboards, station information billboards, store information billboards, exhibition billboards, TV walls, etc.). A larger-sized tiled display formed by tiling smaller-sized display panels can more flexibly provide various sizes required by consumers.

### SUMMARY OF THE INVENTION

One object of this invention is to disclose a tiled display comprising a plurality of displays tiled with each other, and each of the display comprising: a transparent rigid mother substrate with a top surface, a bottom surface opposite to the top surface, and a plurality of cutting edges sandwiched between the top surface and the bottom surface; and a flexible display panel formed on the transparent rigid mother substrate, and the flexible display panel comprising a flexible substrate, a pixel area, a first external circuit area and a second external circuit area, wherein the pixel area is located on the top surface of the transparent rigid mother substrate, and the first external circuit area are located outside of the transparent rigid mother substrate and electrically connected with a plurality of scanning lines of the display panel, and the second external circuit area are located outside of the transparent rigid mother substrate and electrically connected with a plurality of data lines of the display panel, and the first external circuit area and the second external circuit area are respectively back-folded through one of the cutting edges and fasten on the back surface of the transparent rigid mother substrate; wherein each of the displays is tiled with the other displays adjacent thereto by at least one cutting edge thereof to form the tiled display.

The tiled display as mentioned above, wherein the transparent rigid mother substrate is a glass substrate, a silicon substrate, a quartz substrate or a sapphire substrate.

The tiled display as mentioned above, wherein the flexible substrate is formed by a material selected from one of the group consisting of Polyester resin, Polyimide (PI), Modified Polyimide (MPI), Covalent Organic Framework (COF), Liquid Photo-Imageable (LPI), Liquid Crystal Polymer (LCP), Polytetrafluoroethylene (PTFE) and flexible epoxy bonded fiber-glass board, or combinations thereof.

The tiled display as mentioned above, wherein the cutting edges are passivated.

The tiled display as mentioned above, wherein the cutting edges are passivated by mechanically polishing, irradiating with a long wavelength laser, or forming a cured UV resin thereon.

The tiled display as mentioned above, wherein each of the displays is tiled with the other displays adjacent thereto by an adhesive formed on at least one cutting edge therebetween to form the tiled display.

The tiled display as mentioned above, further comprising a fasten frame to make the displays tiled with each other be fasten therein.

Another object of this invention is to disclose a method of manufacturing a tiled display, comprising the steps: providing a plurality of displays, wherein each of the display comprises a transparent rigid mother substrate with a top surface, a bottom surface opposite to the top surface, and a plurality of cutting edges sandwiched between the top surface and the bottom surface; and a flexible display panel formed on the transparent rigid mother substrate, and the flexible display panel comprising a flexible substrate, a pixel area, a first external circuit area and a second external circuit area, wherein the pixel area is located on the top surface of the transparent rigid mother substrate, and the first external circuit area are located outside of the transparent rigid mother substrate and electrically connected with a plurality of scanning lines of the display panel, and the second external circuit area are located outside of the transparent rigid mother substrate and electrically connected with a plurality of data lines of the display panel, and the first external circuit area and the second external circuit area are respectively back-folded through one of the cutting edges and fasten on the back surface of the transparent rigid mother substrate; and tiling the displays to form the tiled display by tiling each of the displays with the other displays adjacent thereto by at least one cutting edge thereof.

The method as mentioned above, wherein the transparent rigid mother substrate is a glass substrate, a silicon substrate, a quartz substrate or a sapphire substrate.

The method as mentioned above, wherein the flexible substrate is formed by a material selected from one of the group consisting of Polyester resin, Polyimide (PI), Modified Polyimide (MPI), Covalent Organic Framework (COF), Liquid Photo-Imageable (LPI), Liquid Crystal Polymer (LCP), Polytetrafluoroethylene (PTFE) and flexible epoxy bonded fiber-glass board, or combinations thereof.

The method as mentioned above, wherein the cutting edges are passivated.

The method as mentioned above, wherein the cutting edges are passivated by mechanically polishing, irradiating with a long wavelength laser, or forming a cured UV resin thereon.

The method as mentioned above, wherein each of the displays is tiled with the other displays adjacent thereto by an adhesive formed on at least one cutting edge therebetween to form the tiled display.

The method as mentioned above, further comprising a step of providing a fasten frame to make the displays tiled with each other be fasten therein.

### BRIEF DESCRIPTION OF THE DRAWINGS

FIGS. 1A and 1B are a top view and a bottom view of a display 10 according to this present invention.

FIGS. 1C and 1D are a bottom view and a top view of a display 100 for manufacturing a tiled display according to this present invention.

FIG. 2 is prospective view of a tiled display 200 according to Embodiment 1 of this present invention.

FIG. 3 is prospective view of a tiled display 300 according to Embodiment 2 of this present invention.

FIG. 4 is prospective view of a tiled display 400 according to Embodiment 3 of this present invention.

FIG. 5 is prospective view of a tiled display 500 according to Embodiment 4 of this present invention.

### DETAILED DESCRIPTION OF THE INVENTION

The detailed description provided below in connection with the appended drawings is intended as a description of the present examples and is not intended to represent the only forms in which the present example may be constructed or utilized. The description sets forth the functions of the example and the sequence of steps for constructing and operating the example. However, the same or equivalent functions and sequences may be accomplished by different examples.

In the following description, numerous specific details are described in detail in order to enable the reader to fully understand the following examples. However, embodiments of the present invention may be practiced in case no such specific details. In other cases, in order to simplify the drawings the structure of the apparatus known only schematically depicted in figures.

### Embodiment 1

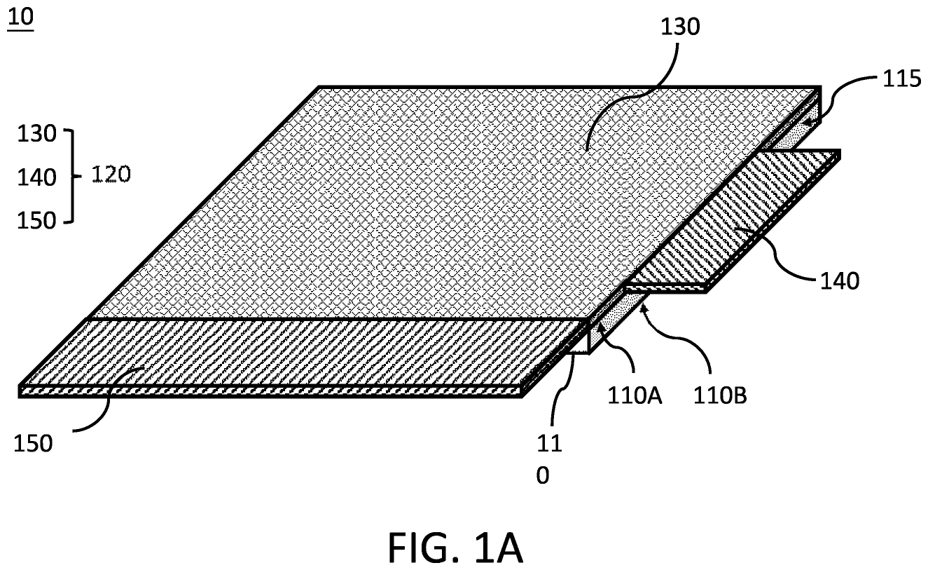

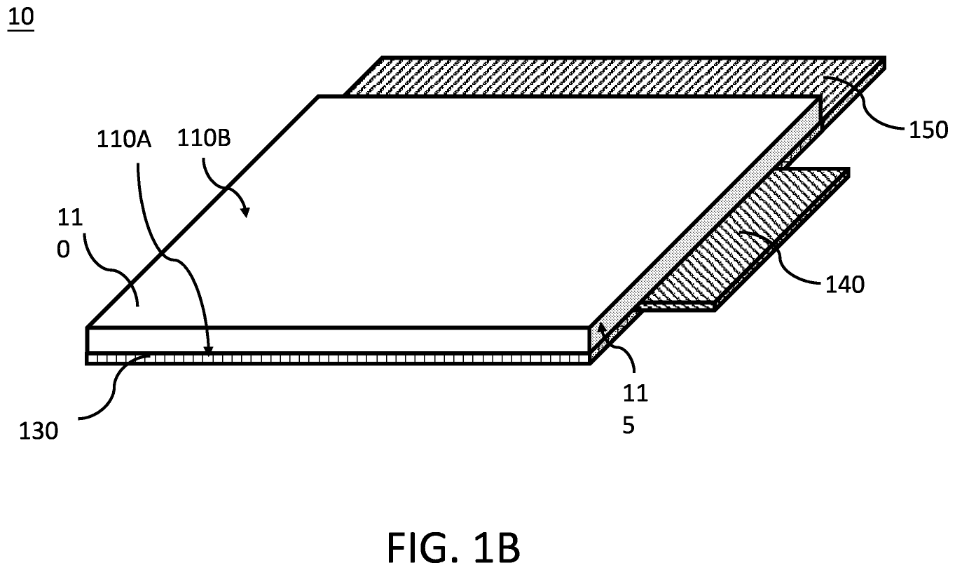

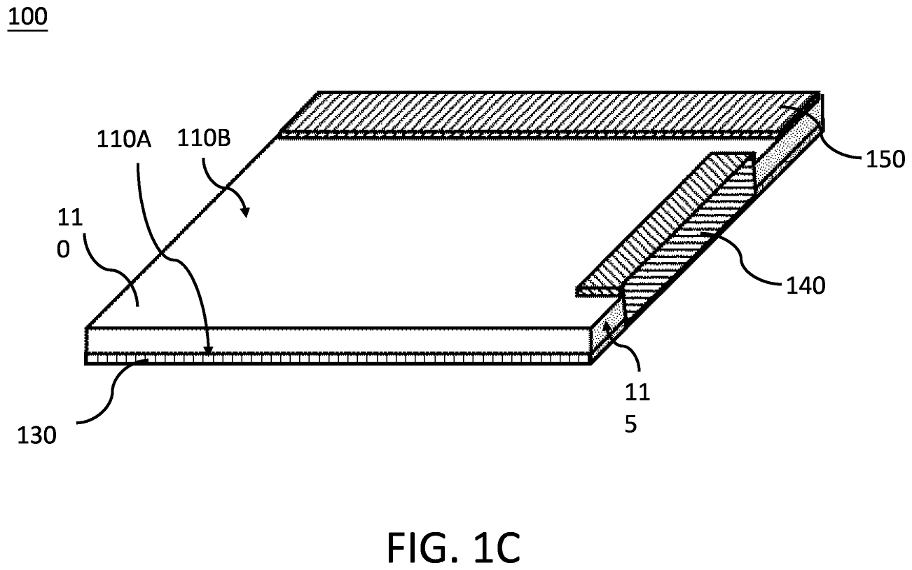

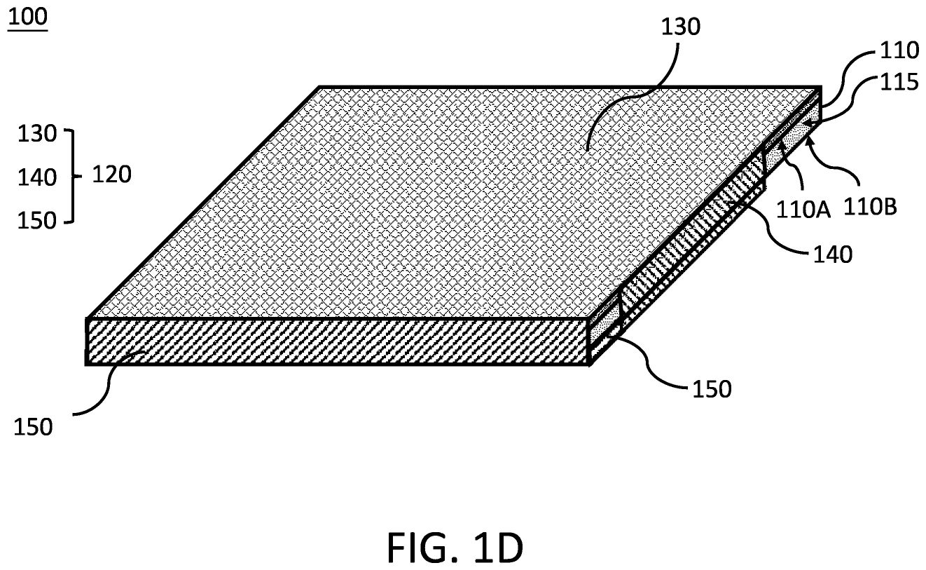

First, a display 10 as shown in FIGS. 1A˜1B was provided. As shown in FIGS. 1A˜1B, the display 10 comprises a transparent rigid mother substrate 110 and a flexible display panel 120 formed on the transparent rigid mother substrate 110. The transparent rigid mother substrate 110 comprises a top surface 110A, a bottom surface 110B opposite to the top surface 110A and a plurality of cutting edges 115 sandwiched between the top surface 110A and the bottom surface 110B. The flexible display panel 120 comprises a flexible substrate (not shown), a pixel area 130, a first external circuit area 140 and a second external circuit area 150, wherein the pixel area 130 is located on the top surface 110A of the transparent rigid mother substrate 110, and the first external circuit area 140 are located outside of the transparent rigid mother substrate 110 and electrically connected with a plurality of scanning lines (not shown) of the display panel 10, and the second external circuit area 150 are located outside of the transparent rigid mother substrate 110 and electrically connected with a plurality of data lines (not shown) of the display panel 10.

The flexible display panel 120 can be for example but not limited to a flexible LED display panel, a flexible micro-LED display panel, an organic LED display (OLED) panel or an electronic paper (e-paper) display. A flexible micro-LED display panel is exemplarily used as the flexible display panel 120 in this Embodiment 1. Other flexible display panels as mentioned above can also be used if required.

The transparent rigid mother substrate 110 can be for example but not limited to a glass substrate, a silicon substrate, a quartz substrate or a sapphire substrate. A glass substrate is exemplarily used as the transparent rigid mother substrate 110 in this Embodiment 1. Other transparent rigid mother substrates as mentioned above can also be used if required.

The above-mentioned flexible substrate (not shown) can be a material selected from one of the group consisting of Polyester resin, Polyimide (PI), Modified Polyimide (MPI), Covalent Organic Framework (COF), Liquid Photo-Imageable (LPI), Liquid Crystal Polymer (LCP), Polytetrafluoroethylene (PTFE) and flexible epoxy bonded fiber-glass board, or combinations thereof. The polyimide (PI) is exemplarily used as a material of the flexible substrate in this Embodiment 1. Other materials as mentioned above can also be used if required.

Secondly, please refer to FIGS. 1C˜1D. The first external circuit area 140 and the second external circuit area 150 of the display panel 10 were respectively back-folded through one of the cutting edges 115 and fasten on the back surface 110B of the transparent rigid mother substrate 110 by for example but not limited to a tape, an adhesive or a fasten mechanism to obtain a display panel 100 for tiling as shown in FIGS. 1C˜1D.

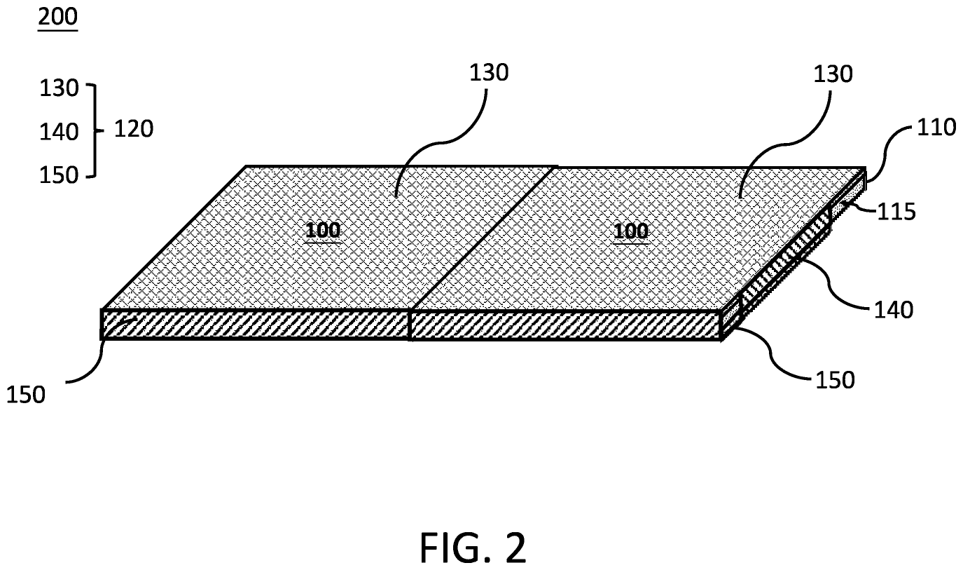

Finally, please refer to FIG. 2. Two display panels 100 for tiling as shown in FIGS. 1C˜1D were provided to form a tiled display 200 as shown in FIG. 2 by tiling one of the displays panels 100 for tiling with the other display panel 100 for tiling adjacent thereto by at least one edge (not labeled) thereof.

According to other embodiments, the cutting edges 115 of the transparent rigid mother substrate 110 were further passivated by for example but not limited to mechanically polishing, irradiating with a long wavelength laser, or forming a cured UV resin (not shown) thereon to make the cutting edges 115 more flat and not sharp and avoid the first external circuit area 140 and the second external circuit area 150 of the display panel 10 be damaged during be respectively back-folded through one of the cutting edges 115 and fasten on the back surface 110B of the transparent rigid mother substrate 110. The cutting edges 115 can be passivated for example but not limited to by mechanically polishing by a polishing wheel to make the cutting edges 115 more flat and not sharp, or irradiating with a long wavelength laser for example but not limited to a CO₂ laser with a wavelength of 9.4 μm˜10.6 μm under a power of 500 W for 2˜3 seconds to make the cutting edges 115 be heated and become more and not sharp thereafter. The cutting edges 115 can also be passivated for example but not limited to by coating a UV resin (not shown) with a thickness of 10 μm on the cutting edges 115 and curing by UV thereafter to form a cured UV resin (not shown) on the cutting edges 115 to make the cutting edges 115 more flat and not sharp

According to other Embodiments of this present application, each of the display panels 100 for tiling was tiled with the other displays adjacent thereto by an adhesive (not shown) for example but not limited to a silicone resin or a polyurethane (PU) resin formed on at least one edge (not labeled) therebetween to form the tiled display 200.

### Example 2

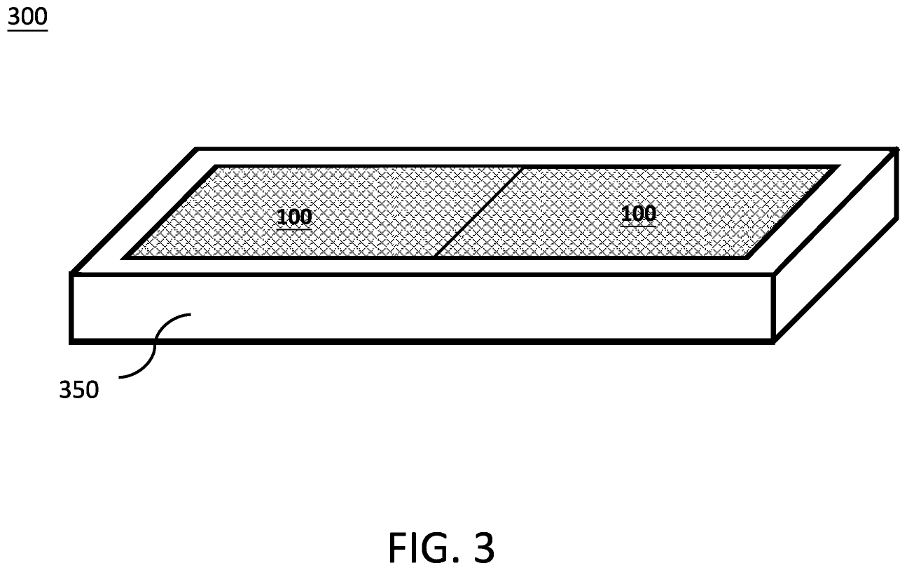

Please refer to FIG. 3. FIG. 3 is prospective view of a tiled display 300 according to Embodiment 2 of this present invention. The major difference between the tiled display 300 according to Embodiment 2 and the tiled display 200 according to Embodiment 1 is that the tiled display 300 further comprises a frame 350 made of for example metal, alloy, plastic, ceramic, carbon-fiber or composite material, wherein the frame 350 was provided to form a tiled display 300 as shown in FIG. 3 by making the two display panels 100 for tiling be tiled with each other and be fasten therein.

According to other Embodiments of this present application, each of the display panels 100 for tiling was tiled with the other displays adjacent thereto by an adhesive (not shown) for example but not limited to a silicone resin or a polyurethane (PU) resin formed on at least one edge (not labeled) therebetween to make the display panels 100 for tiling tiled with each other, and a frame 350 as mentioned above was provided to form a tiled display 300 as shown in FIG. 3 by making the display panels 100 for tiling tiled with each other be fasten therein.

### Embodiment 3

First, a display 10 as shown in FIGS. 1A˜1B was provided. As shown in FIGS. 1A˜1B, the display 10 comprises a transparent rigid mother substrate 110 and a flexible display panel 120 formed on the transparent rigid mother substrate 110. The transparent rigid mother substrate 110 comprises a top surface 110A, a bottom surface 110B opposite to the top surface 110A and a plurality of cutting edges 115 sandwiched between the top surface 110A and the bottom surface 110B. The flexible display panel 120 comprises a flexible substrate (not shown), a pixel area 130, a first external circuit area 140 and a second external circuit area 150, wherein the pixel area 130 is located on the top surface 110A of the transparent rigid mother substrate 110, and the first external circuit area 140 are located outside of the transparent rigid mother substrate 110 and electrically connected with a plurality of scanning lines (not shown) of the display panel 10, and the second external circuit area 150 are located outside of the transparent rigid mother substrate 110 and electrically connected with a plurality of data lines (not shown) of the display panel 10.

The flexible display panel 120 can be for example but not limited to a flexible LED display panel, a flexible micro-LED display panel, an organic LED display (OLED) panel or an electronic paper (e-paper) display. A flexible micro-LED display panel is exemplarily used as the flexible display panel 120 in this Embodiment 1. Other flexible display panels as mentioned above can also be used if required.

The transparent rigid mother substrate 110 can be for example but not limited to a glass substrate, a silicon substrate, a quartz substrate or a sapphire substrate. A glass substrate is exemplarily used as the transparent rigid mother substrate 110 in this Embodiment 1. Other transparent rigid mother substrates as mentioned above can also be used if required.

The above-mentioned flexible substrate (not shown) can be a material selected from one of the group consisting of Polyester resin, Polyimide (PI), Modified Polyimide (MPI), Covalent Organic Framework (COF), Liquid Photo-Imageable (LPI), Liquid Crystal Polymer (LCP), Polytetrafluoroethylene (PTFE) and flexible epoxy bonded fiber-glass board, or combinations thereof. The polyimide (PI) is exemplarily used as a material of the flexible substrate in this Embodiment 1. Other materials as mentioned above can also be used if required.

Secondly, please refer to FIGS. 1C˜1D. The first external circuit area 140 and the second external circuit area 150 of the display panel 10 were respectively back-folded through one of the cutting edges 115 and fasten on the back surface 110B of the transparent rigid mother substrate 110 by for example but not limited to a tape, an adhesive or a fasten mechanism to obtain a display panel 100 for tiling as shown in FIGS. 1C˜1D.

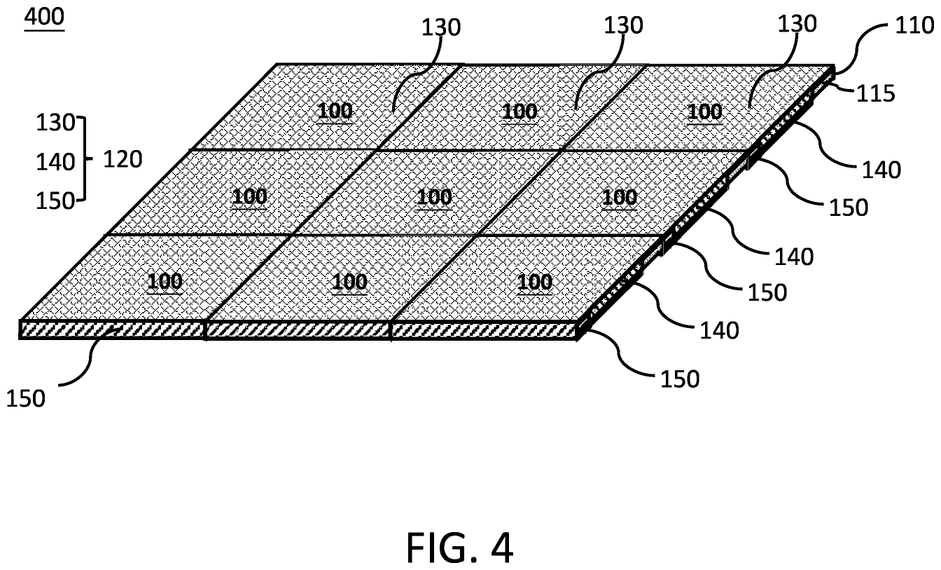

Finally, please refer to FIG. 4. A plurality of display panels 100 for tiling as shown in FIGS. 1C˜1D were provided to form a tiled display 400 as shown in FIG. 4 by tiling one of the displays panels 100 for tiling with the other display panel 100 for tiling adjacent thereto by at least one edge (not labeled) thereof.

According to other embodiments, the cutting edges 115 of the transparent rigid mother substrate 110 were further passivated by for example but not limited to mechanically polishing, irradiating with a long wavelength laser, or forming a cured UV resin (not shown) thereon to make the cutting edges 115 more flat and not sharp and avoid the first external circuit area 140 and the second external circuit area 150 of the display panel 10 be damaged during be respectively back-folded through one of the cutting edges 115 and fasten on the back surface 110B of the transparent rigid mother substrate 110. The cutting edges 115 can be passivated for example but not limited to by mechanically polishing by a polishing wheel to make the cutting edges 115 more flat and not sharp, or irradiating with a long wavelength laser for example but not limited to a CO₂ laser with a wavelength of 9.4 μm˜10.6 μm under a power of 500 W for 2˜3 seconds to make the cutting edges 115 be heated and become more and not sharp thereafter. The cutting edges 115 can also be passivated for example but not limited to by coating a UV resin (not shown) with a thickness of 10 μm on the cutting edges 115 and curing by UV thereafter to form a cured UV resin (not shown) on the cutting edges 115 to make the cutting edges 115 more flat and not sharp

According to other Embodiments of this present application, each of the display panels 100 for tiling was tiled with the other displays adjacent thereto by an adhesive (not shown) for example but not limited to a silicone resin or a polyurethane (PU) resin formed on at least one edge (not labeled) therebetween to form the tiled display 400.

### Embodiment 4

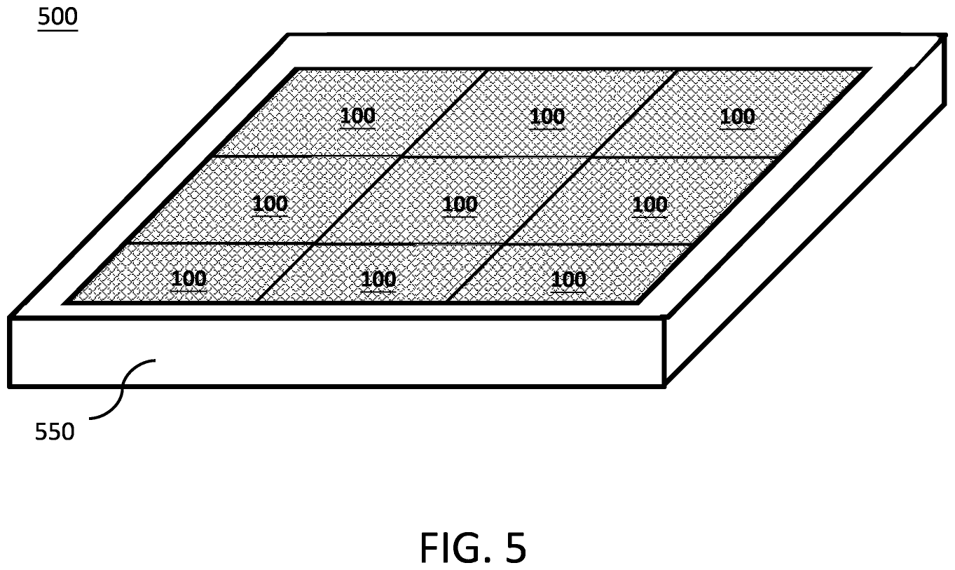

Please refer to FIG. 5. FIG. 5 is prospective view of a tiled display 500 according to Embodiment 4 of this present invention. The major difference between the tiled display 500 according to Embodiment 4 and the tiled display 400 according to Embodiment 3 is that the tiled display 500 further comprises a frame 550 made of for example metal, alloy, plastic, ceramic, carbon-fiber or composite material, wherein the frame 550 was provided to form a tiled display 500 as shown in FIG. 4 by making the display panels 100 for tiling be tiled with each other be fasten therein.

According to other Embodiments of this present application, each of the display panels 100 for tiling was tiled with the other displays adjacent thereto by an adhesive (not shown) for example but not limited to a silicone resin or a polyurethane (PU) resin formed on at least one edge (not labeled) therebetween to make the display panels 100 for tiling be tiled, and a frame 350 as mentioned above was provided to form a tiled display 500 as shown in FIG. 4 by making the display panels 100 for tiling tiled with each other be fasten therein.

Although particular embodiments have been shown and described, it should be understood that the above discussion is not intended to limit the present invention to these embodiments. Persons skilled in the art will understand that various changes and modifications may be made without departing from the scope of the present invention as literally and equivalently covered by the following claims.

What is claimed is:

1. A tiled display comprising a plurality of displays tiled with each other, and each of the display comprising:
a transparent rigid mother substrate with a top surface, a bottom surface opposite to the top surface, and a plurality of cutting edges sandwiched between the top surface and the bottom surface; and
a flexible display panel formed on the transparent rigid mother substrate, and the flexible display panel comprising a flexible substrate, a pixel area, a first external circuit area and a second external circuit area, wherein the pixel area is located on the top surface of the transparent rigid mother substrate, and the first external circuit area are located outside of the transparent rigid mother substrate and electrically connected with a plurality of scanning lines of the display panel, and the second external circuit area are located outside of the transparent rigid mother substrate and electrically connected with a plurality of data lines of the display panel, and the first external circuit area and the second external circuit area are respectively back-folded through one of the cutting edges and fasten on the back surface of the transparent rigid mother substrate;
wherein each of the displays is tiled with the other displays adjacent thereto by at least one cutting edge thereof to form the tiled display.

2. The tiled display as claimed in claim 1, wherein the transparent rigid mother substrate is a glass substrate, a silicon substrate, a quartz substrate or a sapphire substrate.

3. The tiled display as claimed in claim 1, wherein the flexible substrate is formed by a material selected from one of the group consisting of Polyester resin, Polyimide (PI), Modified Polyimide (MPI), Covalent Organic Framework (COF), Liquid Photo-Imageable (LPI), Liquid Crystal Polymer (LCP), Polytetrafluoroethylene (PTFE) and flexible epoxy bonded fiber-glass board, or combinations thereof.

4. The tiled display as claimed in claim 1, wherein the cutting edges are passivated.

5. The tiled display as claimed in claim 4, wherein the cutting edges are passivated by mechanically polishing, irradiating with a long wavelength laser, or forming a cured UV resin thereon.

6. The tiled display as claimed in claim 1, wherein each of the displays is tiled with the other displays adjacent thereto by an adhesive formed on at least one cutting edge therebetween to form the tiled display.

7. The tiled display as claimed in claim 1, further comprising a fasten frame to make the displays tiled with each other be fasten therein.

8. A method of manufacturing a tiled display, comprising the steps:
providing a plurality of displays, wherein each of the display comprises:
a transparent rigid mother substrate with a top surface, a bottom surface opposite to the top surface, and a plurality of cutting edges sandwiched between the top surface and the bottom surface; and
a flexible display panel formed on the transparent rigid mother substrate, and the flexible display panel comprising a flexible substrate, a pixel area, a first external circuit area and a second external circuit area, wherein the pixel area is located on the top surface of the transparent rigid mother substrate, and the first external circuit area are located outside of the transparent rigid mother substrate and electrically connected with a plurality of scanning lines of the display panel, and the second external circuit area are located outside of the transparent rigid mother substrate and electrically connected with a plurality of data lines of the display panel, and the first external circuit area and the second external circuit area are respectively back-folded through one of the cutting edges and fasten on the back surface of the transparent rigid mother substrate; and
tiling the displays to form the tiled display by tiling each of the displays with the other displays adjacent thereto by at least one cutting edge thereof.

9. The method as claimed in claim 8, wherein the transparent rigid mother substrate is a glass substrate, a silicon substrate, a quartz substrate or a sapphire substrate.

10. The method as claimed in claim 8, wherein the flexible substrate is formed by a material selected from one of the group consisting of Polyester resin, Polyimide (PI), Modified Polyimide (MPI), Covalent Organic Framework (COF), Liquid Photo-Imageable (LPI), Liquid Crystal Polymer (LCP), Polytetrafluoroethylene (PTFE) and flexible epoxy bonded fiber-glass board, or combinations thereof.

11. The method as claimed in claim 8, wherein the cutting edges are passivated.

12. The method as claimed in claim 11, wherein the cutting edges are passivated by mechanically polishing, irradiating with a long wavelength laser, or forming a cured UV resin thereon.

13. The method as claimed in claim 8, wherein each of the displays is tiled with the other displays adjacent thereto by an adhesive formed on at least one cutting edge therebetween to form the tiled display.

14. The method as claimed in claim 8, further comprising a step of providing a fasten frame to make the displays tiled with each other be fasten therein.
